(19) United States
(12) Patent Application Publication
(10) Pub. No.: US 2015/0301090 A1
(43) Pub. Date: Oct. 22, 2015

(54) Electric Circuit Isolator/Tester

(71) Applicant: Timothy Shane McClure, Desert Hot Springs, CA (US)

(72) Inventor: Timothy Shane McClure, Desert Hot Springs, CA (US)

(21) Appl. No.: 14/257,068

(22) Filed: Apr. 21, 2014

(51) Int. Cl. G01R 19/15; G01R 19/00; G01R 1/04

(52) U.S. Cl. CPC G01R 19/15; G01R 1/0416; G01R 19/0046

(57) ABSTRACT

Disclosed is a device that uses a circuit board to isolate and test electrical circuits so as to generate an audible signal when electric current is flowing through the circuit but is quiet when electric current is not flowing. The circuit board may contain a wireless transmitter circuit that allows the audible signal to be heard through a headset.

### CROSS REFERENCE TO RELATED APPLICATIONS

The present invention claims the benefit of U.S. Provisional Application Ser. No. 61/878,292, filed 13 Sep. 2013, entitled “Electric Circuit Isolator Tester”, by Timothy S. McClure.

### BACKGROUND OF THE INVENTION

a. Field of the Invention

The present invention generally pertains to measuring and testing of electric circuits and more particularly to detecting faults in an electric circuit that cause the circuit to be open.

b. Description of the Background

For safety reasons, electricians should always turn off electric current to any electrical outlet they will be examining before beginning to work on that outlet. For residential or commercial properties, turning off electric current often involves shutting off all or part of a set of circuit breakers that control electric current to the entire property.

To ensure that electric current is not flowing into an outlet under examination, a device is often connected to the outlet that visually indicates a voltage when electric current is flowing and zero voltage when electric current is not flowing. In order to see the testing machine's visual indication, an electrician must either spend time walking back and forth between the outlet under examination and the set of circuit breakers until he has isolated and turned off the correct circuit breaker(s) for the given outlet, or engage a second person to do nothing but watch the testing machine and call to the electrician when the visual indication is zero. Both of these methods are inefficient and would be substantially improved by using a device that emits an audible signal when electric current is flowing instead of a visual signal.

U.S. Pat. No. 5,331,283 (Sheldon), U.S. Pat. No. 6,246,225 (Schaefer) and U.S. Pat. No. 6,657,435 (Brown) disclose an electric circuit that provides an audible signal when electric current is flowing through the circuit but is quiet when electric current is not flowing. However, Sheldon specifically claims only the use of transformers and windings to create the electrical circuit and was conceived in an era when two-pronged electrical outlets were more common. Brown discloses the use of a four-way bridge rectifier to create the circuit. Schaefer discloses the use of an electrically insulating epoxy to help prevent electrical shock.

It would therefore be advantageous to have a circuit isolator/tester that does not use a transformer, windings or four-way bridge rectifier but uses more modern technology (including circuit boards and wireless transmitters) instead. It would further be advantageous to have a circuit isolator/tester that does not require an electrically-insulating epoxy to help prevent electrical shock.

### SUMMARY OF THE INVENTION

The present invention overcomes the disadvantages and limitations of the prior art by providing a device that uses a circuit board to isolate and test electrical circuits so as to generate an audible signal when electric current is flowing through the circuit but is quiet when electric current is not flowing. One embodiment includes a wireless transmitter to allow operation at long distances.

The present invention may therefore comprise a device for isolating and testing electrical circuits, comprising: an external case made of fireproof material; a three-pronged plug that plugs into and tests a three-pronged electrical outlet; a set of wires; two clips that attach to the set of wires and can be attached to bare electrical wires to detect current flow through the bare electrical wires; a circuit board that contains electrical components of the device for isolating and testing electrical circuits; a sound device that connects to the circuit board and makes an audible sound when current flows through it; a speaker that connects to the sound device and amplifies the sound created by the sound device; a first diode that connects to the circuit board and allows current to flow from the three-pronged plug to the sound device; a first fusible link that connects to the circuit board, allows current to flow from the three-pronged lug to the first diode, and melts and opens whenever too much current flows from the three-pronged plug to the sound device; a second diode that connects to the circuit board and allows current to flow from the set of wires to the sound device; and a second fusible link that connects to the circuit board, allows current to flow from the set of wires to the second diode, and melts and opens whenever too much current flows from the set of wires to the second diode. The external case may be made of fireproof material certified by Underwriters Laboratories as fireproof, such as acrylonitrile butadiene styrene. The circuit board may further contain a wireless transmitter circuit allowing a headset to detect the sound created by the sound device and amplified by the speaker, as well as a switch connected to the external case and the circuit board that allows switching between wired and wireless transmission of the sound created by the sound device and amplified by the speaker.

The advantages of the present invention are increased safety to a user and the capability of using a wireless signal to cue a user whether or not current is flowing in a circuit.

### BRIEF DESCRIPTION OF THE DRAWINGS

In the drawings,

FIG. 1 is an illustration of one embodiment of the external case of the present invention.

FIG. 2 is an illustration of one embodiment of the internal area of the present invention.

FIG. 3 is a schematic representation of a second embodiment of the present invention that includes use of a wireless transmitter and thus extends the usefulness of the present invention.

### DETAILED DESCRIPTION OF THE INVENTION

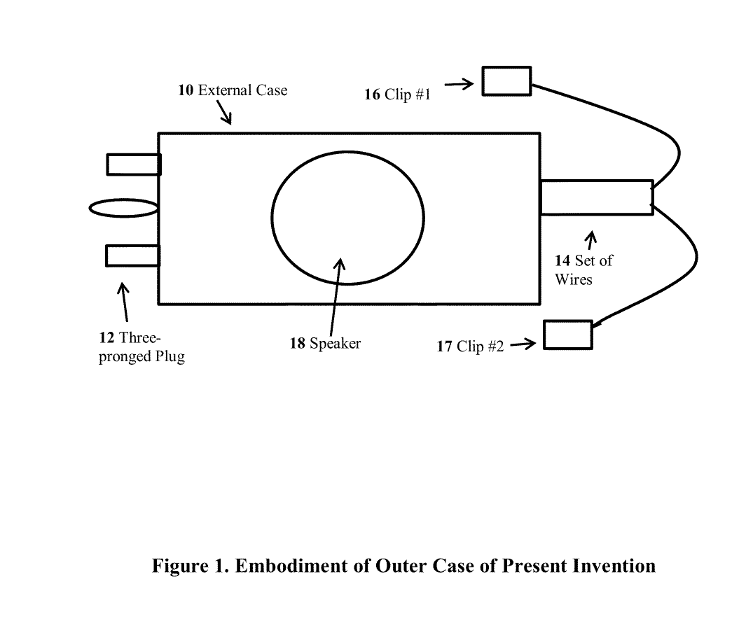

FIG. 1 illustrates a top view of one embodiment of the external case 10 of the present invention. The external case 10, which does not need an insulating epoxy to prevent shock, may contain a three-pronged plug 12 that can be plugged into a modern three-pronged electrical outlet, a set of wires 14 that is attached to two separate clips 16 and 17, and a speaker 18.

In one use of the present invention, a user may carry the external case 10 to a modern three-pronged electrical outlet to be tested and connect the three-pronged plug 12 to a modern three-pronged electrical outlet. If electrical current is detected by the three-pronged plug 12, the speaker 18 may emit an audible sound. The user may then go a short distance away (up to approximately 50 yards) from the modern three-pronged electrical outlet without carrying the external case 10 and examine a set of circuit breakers. The user may turn off circuit breakers one at a time until the speaker 18 no longer emits an audible sound, thus indicating that the modern three-pronged electrical outlet now has no current flowing through it and can thus safely be examined.

In another use of the present invention, a user may employ the set of wires 14 attached to two clips 16 and 17. Each separate clip 16 and 17 may be connected to one of a set of bare electrical wires. If electrical current is flowing through the clips 16 and 17, the speaker 18 may emit an audible sound. The user may then go a short distance away (up to approximately 50 yards) from the set of bare electrical wires without carrying the external case 10 and examine a set of circuit breakers. The user may turn off circuit breakers one at a time until the speaker 18 no longer emits an audible sound, thus indicating that the set of bare electrical wires now has no current flowing through it and can thus safely be examined.

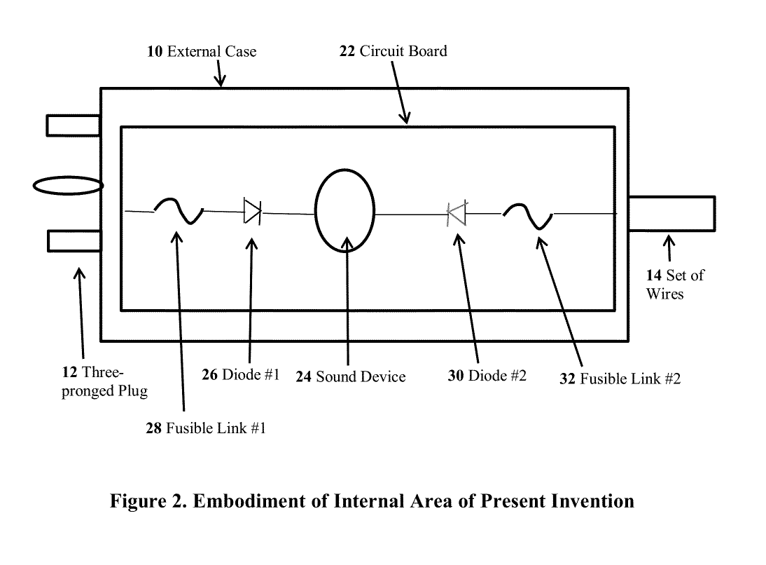

FIG. 2 is an illustration of one embodiment of the internal area of the present invention inside the outer case 10. The internal area may contain a circuit board 22 that is connected to the three-pronged plug 12 and the set of wires 14 that are part of the external case 10. The circuit board 22 may contain a sound device 24 that makes an audible sound when current flows through either a first diode 26 and a first fusible link 28 or separately through a second diode 30 and a second fusible link 32. A separate connection (not seen in FIG. 2) may connect the sound device 24 with the speaker 18 and allow sound created by the sound device 24 to be amplified by the speaker 18. One inventive step of the present invention is the use of a circuit board to contain major elements of the present invention.

When the three-pronged plug 12 is connected to electrical power, the circuit board 22 may also receive electrical power. Current may flow through the first diode 26 and first fusible link 28 but may be physically prevented from flowing through the second diode 30 and second fusible link 32 because of the direction of the second diode 30 as placed on the circuit board 22. Thus, the current through the first diode 26 and first fusible link 28 may all flow through the sound device 24 and then through the speaker 18 in a manner that causes an audible sound through the speaker 18 as long as current is flowing through the first diode 26 and first fusible link 28. When electrical power is removed, current may stop flowing through the first diode 26 and first fusible link 28 and the sound device 24 may no longer emit an audible sound, thus indicating that the modern three-pronged electrical outlet now has no current flowing through it and can thus safely be examined.

If a dangerous amount of current unexpectedly flows through the three-pronged plug 12 due to a fault in wiring, the first fusible link 28 may quickly melt and permanently become open. The current thus stops flowing through the first diode 26, preventing the sound device 24 from emitting an audible sound. This both adds an element of safety when testing a modern three-pronged electrical outlet by preventing damaging levels of electric current that could shock or injure a user from flowing through the present invention and gives notice to a user of a change in current flow.

When the set of wires 14 is attached to a set of bare electrical wires, the circuit board 22 may receive electrical power through the set of wires 14. Current may then flow through the second diode 30 and second fusible link 32 but may be physically prevented from flowing through the first diode 26 and first fusible link 28 because of the direction of the first diode 26 as placed on the circuit board 22. Thus, the current through the second diode 28 and second fusible link 32 may flow through the sound device 24 and then through the speaker 18 in a manner that causes an audible sound through the speaker 18 as long as current is flowing through the second diode 28 and second fusible link 32. When electrical power is removed, current may stop flowing through the second diode 28 and second fusible link 32 and the sound device 24 may no longer emit an audible sound, thus indicating that the set of wires 14 now has no current flowing through it and can thus safely be examined.

If a dangerous amount of current unexpectedly flows through the set of wires 14 due to a fault in wiring, the second fusible link 32 may quickly melt and permanently become open. The current thus stops flowing through the second diode 30, preventing the sound device 24 from emitting an audible sound. This both adds an element of safety when testing a set of wires by preventing damaging levels of electric current that could shock or injure a user from flowing through the present invention and gives notice to a user of a change in current flow.

In some embodiments of the present invention, the external case may be made of a material certified as fireproof by Underwriters Laboratories to improve safety for both the circuit under test and a user. This material may be a version of the polymer “acrylonitrile butadiene styrene” (or ABS).

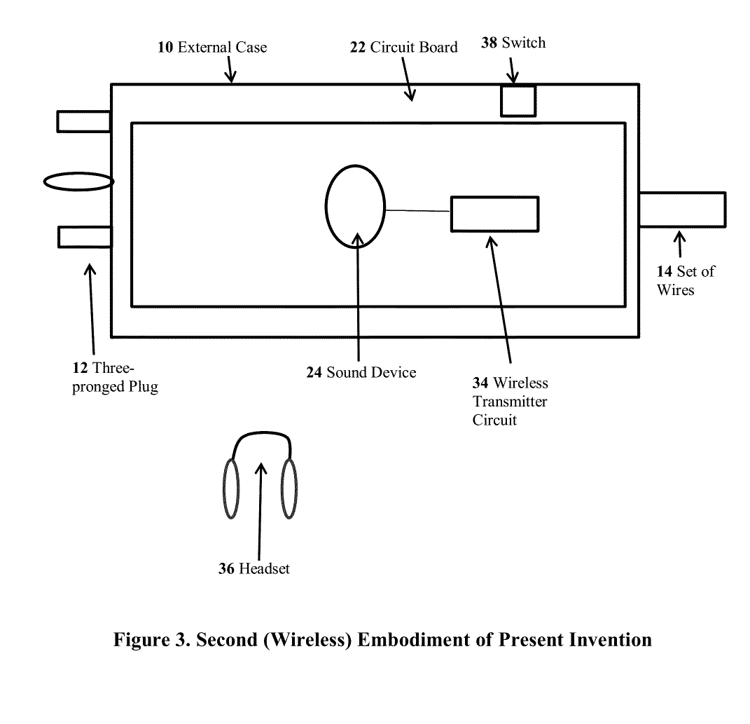

FIG. 3 illustrates a schematic representation of a second embodiment of the present invention that includes use of a wireless transmitter and thus extends the usefulness of the present invention. In addition to the components on the circuit board illustrated in FIG. 2 but not illustrated in FIG. 3, a wireless transmitter circuit 34 may be connected to the circuit board 22 in a way that allows the sound created by the sound device 24 and amplified by the speaker 18 (shown in FIG. 1) to be sent a distance through the air wirelessly and detected only through a headset 36 worn by a user. The sound created by flowing current is thus heard by a user but does not bother other people in the vicinity of the present invention, such as a sleeping baby in a home. A switch 38 may be connected to the external case 10 and circuit board 22 in a manner that allows switching between a wired setup and a wireless setup as desired.

The present invention therefore provides a device that uses a circuit board to isolate and test electrical circuits so as to generate an audible signal when electric current is flowing through the circuit but is quiet when electric current is not flowing.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A device for isolating and testing electrical circuits, comprising:
an external case made of fireproof material;
a three-pronged plug that plugs into and tests a three-pronged electrical outlet;
a set of wires;
two clips that attach to said set of wires and can be attached to bare electrical wires to detect current flow through said bare electrical wires;
a circuit board that contains electrical components of said device for isolating and testing electrical circuits;
a sound device that connects to said circuit board and makes an audible sound when current flows through it;
a speaker that connects to said sound device and amplifies the sound created by said sound device;
a first diode that connects to said circuit board and allows current to flow from said three-pronged plug to said sound device;
a first fusible link that connects to said circuit board, allows current to flow from said three-pronged plug to said first diode, and melts and opens whenever too much current flows from said three-pronged plug to said first diode;
a second diode that connects to said circuit board and allows current to flow from said set of wires to said sound device; and,
a second fusible link that connects to said circuit board, allows current to flow from said set of wires to said second diode, and melts and opens whenever too much current flows from said set of wires to said second diode.

2. The device of claim 1, wherein said fireproof material is certified by Underwriters Laboratories as fireproof.

3. The device of claim 2, wherein said fireproof material is acrylonitrile butadiene styrene.

4. The device of claim 1, wherein said circuit board further contains a wireless transmitter circuit allowing a headset to detect the sound created by said sound device and amplified by said speaker.

5. The device of claim 4, wherein said circuit board further contains a switch connected to said external case and said circuit board that allows switching between wired and wireless transmission of the sound created by said sound device and amplified by said speaker.
